(19) United States
(12) Patent Application Publication
(10) Pub. No.: US 2026/0025974 A1
(43) Pub. Date: Jan. 22, 2026

(54) SEMICONDUCTOR DEVICE

(71) Applicant: Samsung Electronics Co., Ltd., Suwon-si (KR)

(72) Inventors: Sungho Jang, Suwon-si (KR); Junsoo Kim, Suwon-si (KR); Jeonghoon Oh, Suwon-si (KR)

(21) Appl. No.: 19/028,560

(22) Filed: Jan. 17, 2025

(30) Foreign Application Priority Data
Jul. 17, 2024 (KR) 10-2024-0094612

(51) Int. Cl. H10B 12/00; H10B 80/00

(52) U.S. Cl. CPC H10B 12/312; H10B 12/482; H10B 12/488; H10B 80/00; H10B 12/03

(57) ABSTRACT

Provided is a semiconductor device including a first memory pattern including a first word line extending in a first direction from one side of a first active pattern, a second word line extending in the first direction from the other side of the second active pattern, a back gate electrode extending in the first direction and apart from the first and second word lines in a second direction perpendicular to the first direction, a landing pad having one end portion contacting lower surfaces of the first and second active patterns and the other end portion contacting a data storage pattern including a capacitor, a contact node located on upper surfaces of the first and second active patterns, a bit line contacting the contact node and extending in the second direction, a spacer and a bit line shield layer sequentially surrounding an upper surface and a side surface of the bit line, and a bit line plate covering an upper surface of the bit line shield layer, at least one second memory pattern disposed at a different vertical level from the first memory pattern and having a structure vertically symmetrical to the first memory pattern, at least one third memory pattern disposed at a different vertical level from the first memory pattern and being substantially the same as the first memory pattern, and at least two bonding patterns connecting the first, second, and third memory patterns.

### CROSS-REFERENCE TO RELATED APPLICATION

This application is based on and claims priority under 35 USC § 119 to Korean Patent Application No. 10-2024-0094612, filed on Jul. 17, 2024, in the Korean Intellectual Property Office, the disclosure of which is incorporated by reference herein in its entirety.

### BACKGROUND

The inventive concept relates to a semiconductor device. More particularly, the inventive concept relates to a semiconductor device including a vertical channel transistor.

To meet superior performance and economic feasibility, it is necessary to increase the integration density of semiconductor devices. In particular, the integration density of memory devices is an important factor in determining the economic feasibility of products. Because the integration density of two-dimensional (2D) memory devices is mainly determined by the area occupied by a unit memory cell, it is significantly affected by the level of fine pattern formation technology. However, expensive equipment is required to form fine patterns and the area of chip dies is limited, so the integration density of 2D memory devices is still limited, although increasing.

### SUMMARY

Aspects of the inventive concept provide a semiconductor device with improved integration density and electrical characteristics.

In addition, the problems to be solved by the inventive concept are not limited to the problems mentioned above, and other problems may be clearly understood by those skilled in the art from the description below.

In order to achieve the technical problem, the inventive concept provides the following semiconductor device.

According to an aspect of the inventive concept, there is provided a semiconductor device including a first memory pattern, a first bonding pattern formed on the first memory pattern, a second bonding pattern formed on the first bonding pattern, and a second memory pattern formed on the second bonding pattern, wherein the first memory pattern includes a first active pattern including first and second side surface facing away from each other, a second active pattern including third and fourth side surface facing away from each other, a first word line extending in a first direction from the first side surface of the first active pattern, a second word line extending in the first direction from the fourth side surface of the second active pattern, a back gate electrode extending in the first direction and spaced apart from the first and second word lines in a second direction perpendicular to the first direction, data storage patterns each including a capacitor, landing pads each having one end portion contacting a corresponding one of lower surfaces of the first and second active patterns and the other end portion contacting a corresponding one of the data storage patterns, contact nodes each of which disposed on a corresponding one of upper surfaces of the first and second active patterns, bit lines each of which contacting a corresponding one of the contact nodes and extending in the second direction, a bit line shield layer covering upper and side surfaces of the bit line, and a first bit line plate covering an upper surface of the bit line shield layer. The second memory pattern is symmetric to the first memory pattern.

According to another aspect of the inventive concept, there is provided a semiconductor device including a first memory pattern including a first active pattern including first and second side surface facing away from each other, a second active pattern including third and fourth side surface facing away from each other, a first word line extending in a first direction from the first side surface of the first active pattern, a second word line extending in the first direction from the fourth side surface of the second active pattern, a back gate electrode extending in the first direction and being spaced apart from the first and second word lines in a second direction perpendicular to the first direction, data storage patterns each including a capacitor, landing pads each having one end portion contacting a corresponding one of lower surfaces of the first and second active patterns and the other end portion contacting a corresponding one of the data storage patterns, contact nodes each of which located on a corresponding one of upper surfaces of the first and second active patterns, bit lines each of which contacting a corresponding one of the contact nodes and extending in the second direction, a bit line shield layer covering upper and side surfaces of the bit line, and a first bit line plate covering an upper surface of the bit line shield layer. The semiconductor device further includes a second memory pattern is symmetric to the first memory pattern and disposed at a vertical level higher than the first memory pattern, a first bonding pattern and a second bonding pattern connecting the first memory pattern to the second memory pattern, a third memory pattern is symmetric to the first memory pattern and disposed at a vertical level lower than the first memory pattern, and a third bonding pattern and a fourth bonding pattern connecting the third memory pattern to the first memory pattern. The second memory pattern includes a second data storage pattern and a second bit line plate spaced apart from each other. The third memory pattern includes a third data storage pattern and a third bit line plate spaced apart from each other. The first bonding pattern and the third bonding pattern are connected to the first bit line plate and the first data storage pattern of the first memory pattern, respectively. A lower surface and an upper surface of the second bonding pattern are connected to the first bonding pattern and the second bit line plate of the second memory pattern, respectively, and a lower surface and an upper surface of the fourth bonding pattern are connected to the third data storage pattern and the third bonding pattern of the third memory pattern, respectively.

According to another aspect of the inventive concept, there is provided a semiconductor device including a first memory pattern including a first active pattern including first and second side surface facing away from each other, a second active pattern including third and fourth side surface facing away from each other, a first word line extending in a first direction from the first side surface of a first active pattern, a second word line extending in the first direction from the fourth side surface of the second active pattern, a back gate electrode extending in the first direction and spaced apart from the first and second word lines in a second direction perpendicular to the first direction, data storage patterns each including a capacitor, landing pads each having one end portion contacting a corresponding one of lower surfaces of the first and second active patterns and the other end portion contacting a corresponding one of the first data storage patterns, contact nodes each of which located on a corresponding one of upper surfaces of the first and second active patterns, bit lines each of which contacting a corresponding one of the contact nodes and extending in the second direction, a spacer and a bit line shield layer sequentially surrounding an upper surface and a side surface of the bit line, and a bit line plate covering an upper surface of the bit line shield layer, at least one second memory pattern disposed at a different vertical level from the first memory pattern and being symmetric to the first memory pattern, at least one third memory pattern disposed at a different vertical level from the first memory pattern and being symmetric to the first memory pattern, and at least two bonding patterns connecting the first, second, and third memory patterns.

According to another aspect of the inventive concept, a semiconductor device includes a first plurality of sub-cells disposed at a first vertical height level in a first direction; and a second plurality of sub-cells disposed at a second vertical height level in the first direction, wherein each of the first plurality of sub-cells and a corresponding one of the second plurality of sub-cells are parts of a unit cell of a memory cell array, each of the first plurality of sub-cells include a first transistor, and each of the second plurality of sub-cells include a second transistor.

### BRIEF DESCRIPTION OF THE DRAWINGS

Embodiments will be more clearly understood from the following detailed description taken in conjunction with the accompanying drawings in which:

FIGS. 1, 2A, 2B, 3A, 3B, 4A, 4B, 5A, 5B, 6A, 6B, 7A, 7B, 8A, 8B, 8C, 9, 10A and 10B each is a perspective view, a cross-sectional view, or a layout diagram, which illustrate a semiconductor device according to an embodiment of the invention and/or sequential process steps of a method for manufacturing thereof;

FIG. 11 is a perspective view showing a semiconductor device according to another embodiment;

FIG. 12 is a perspective view showing a semiconductor device according to yet another embodiment;

FIG. 13A is a perspective view showing a semiconductor device according to yet another embodiment;

FIG. 14A is a perspective view showing a semiconductor device according to yet another embodiment; and

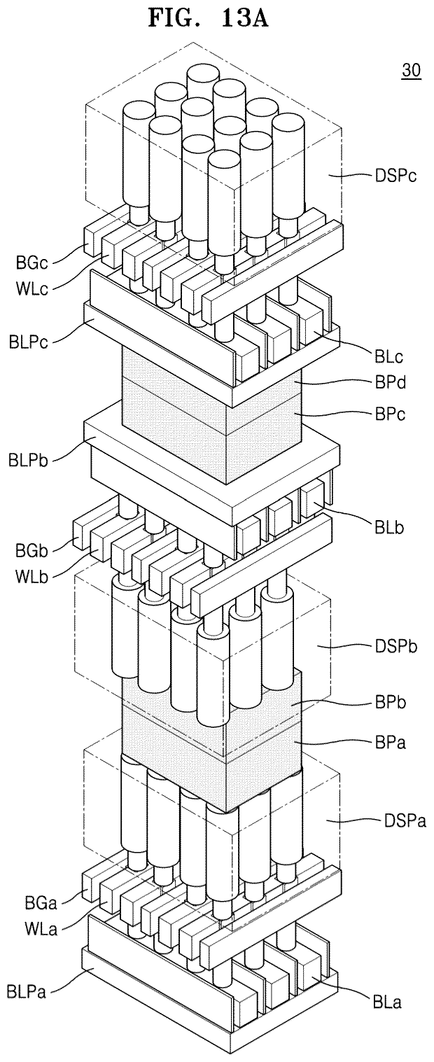

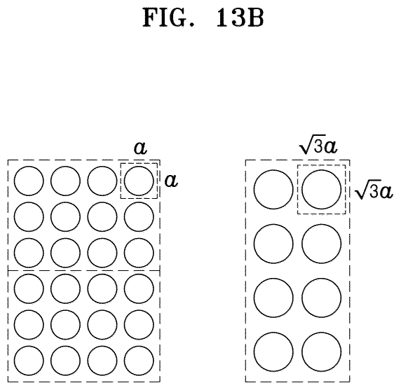

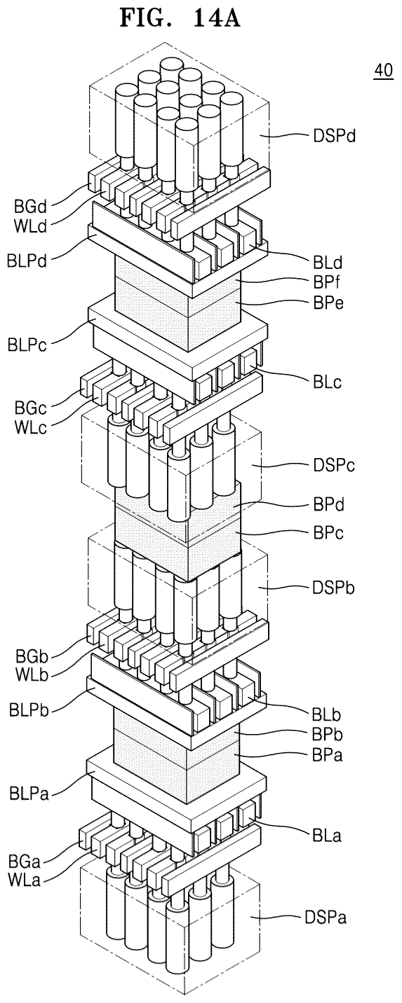

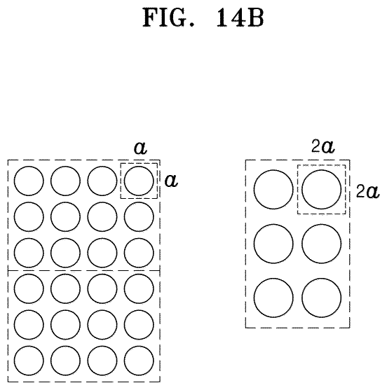

FIGS. 13B and 14B are for plan views illustrating areas occupied by unit memory cells according to the embodiments of the present invention.

### DETAILED DESCRIPTION OF THE EMBODIMENTS

Hereinafter, embodiments are described in detail with reference to the accompanying drawings. The same reference numerals are used for the same components in the drawings, and redundant descriptions thereof may be omitted.

The embodiments may be modified into various forms by those skilled in the art, thus the detailed descriptions and illustrations in the drawings are merely examples that will fall within the spirit and scope of the principles of the invention. Accordingly, it should be understood that the present invention is not limited to the embodiments, but may include all modifications, equivalents, and replacements belonging to the concept and the technical scope of the inventive concept. In describing the embodiments, if a detailed description for a related known art is considered to unnecessarily divert the gist of the inventive concept, such description may be omitted, but would be understood by those skilled in the art.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

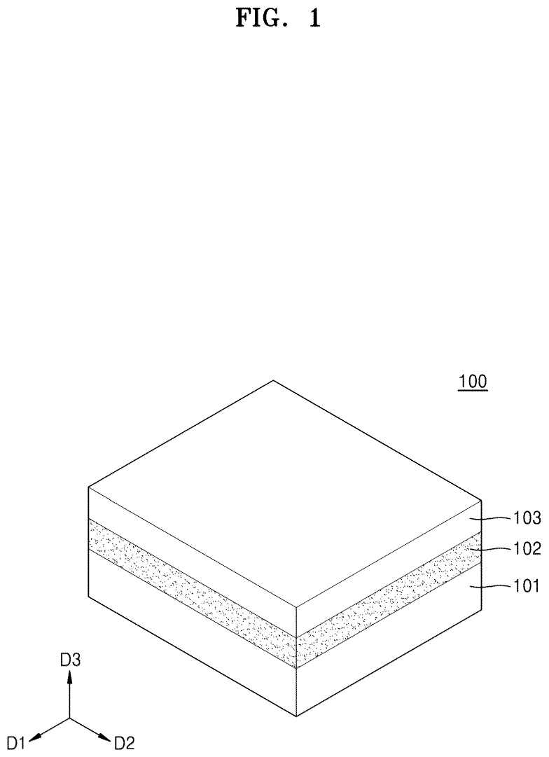

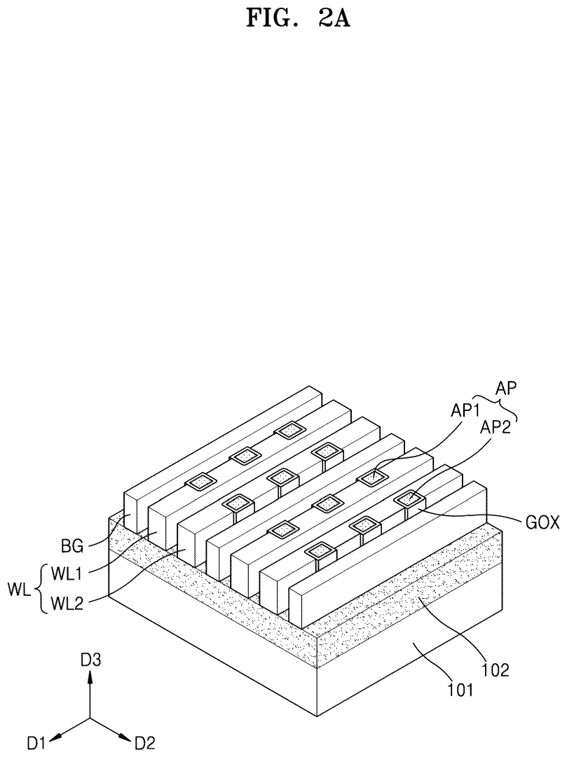

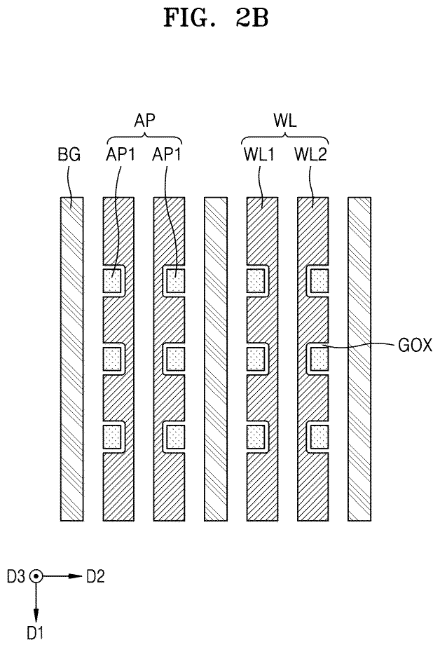

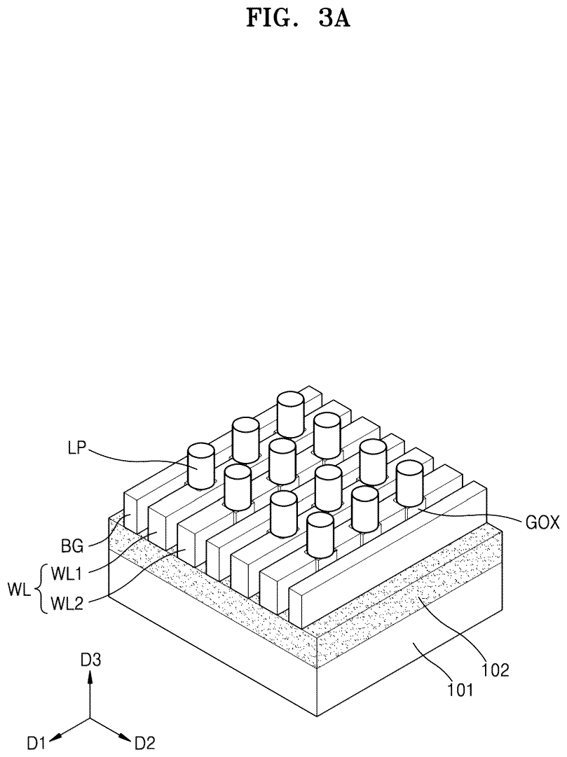

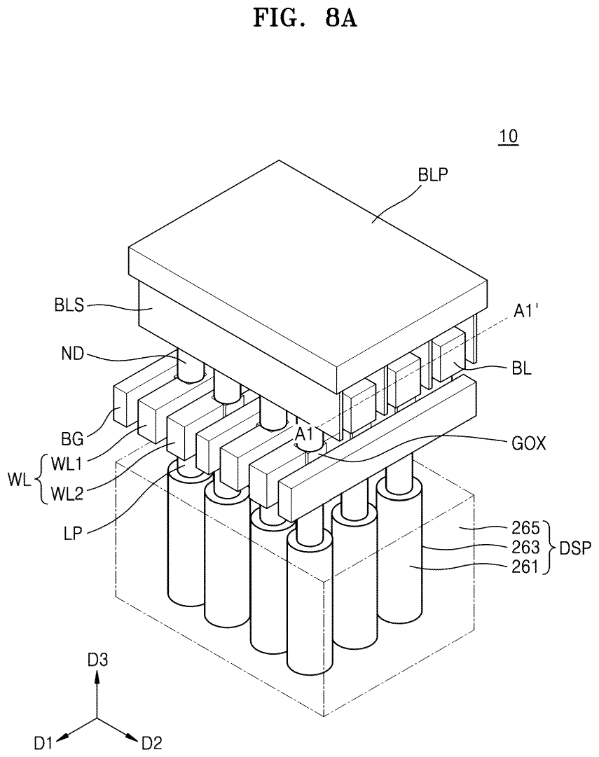

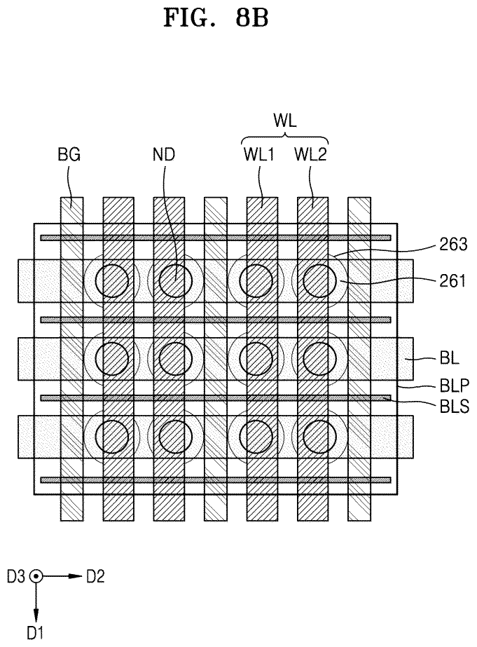

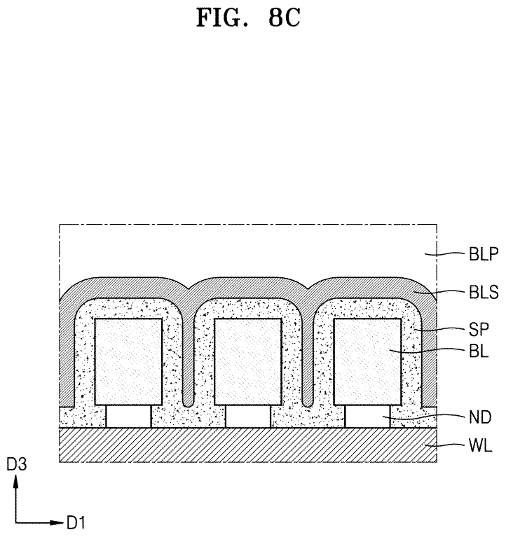

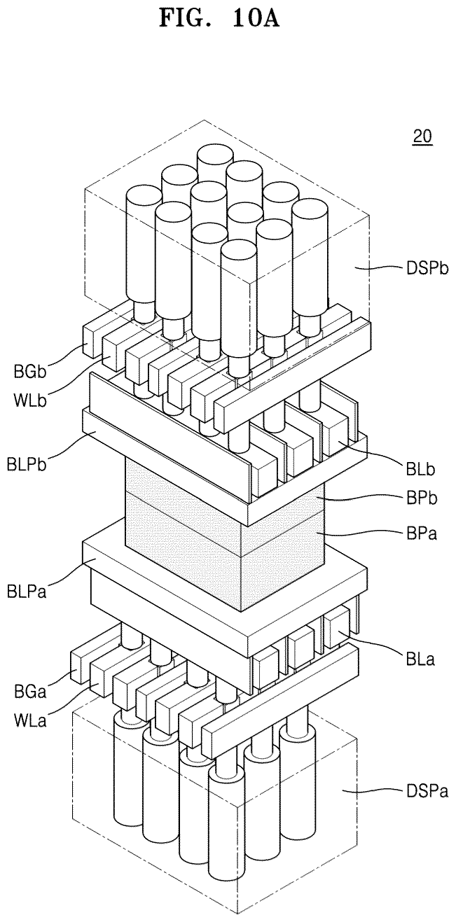

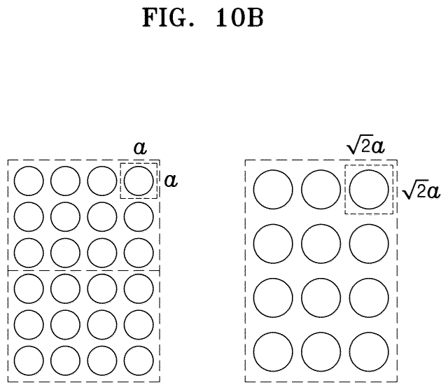

FIGS. 1 to 10B are illustrating a semiconductor device according to an embodiment and/or showing sequential process steps of a method of manufacturing the semiconductor device. In detail, FIGS. 1, 2A, 3A, 4A, 5A, 6A, 7A, 8A, 9, and 10A are perspective views showing a sequential process of a method for manufacturing a semiconductor device, FIGS. 2B, 3B, 4B, 5B, 6B, 7B, and 8B are layout diagrams showing a sequential process of a method for manufacturing the semiconductor device, FIG. 8C is a cross-sectional view illustrating a portion of a section taken along line A1-A1′ of the semiconductor device of FIG. 8A, and FIG. 10B is showing cell layout diagrams to illustrate the relatively decreased area occupied by a unit memory cell according to the embodiment.

First, referring to FIG. 1, a substrate 100 may be provided. The substrate 100 may be one of a semiconductor material (material having semiconductor properties (e.g., silicon, germanium)), an insulating material (e.g., glass, quartz), or an either a semiconductor material or a conductive material which are covered with an insulating material. For example, the substrate 100 may be a silicon on insulator (SOI) structure in which an insulating material 102 is located between two separated silicon materials (layers) 101 and 103.

Referring to FIGS. 2A and 2B, a plurality of patterns may be formed on the silicon material 103 or on the insulating material 102 of the substrate 100 to form an active pattern AP including a channel region, back gate electrodes BG, a word line WL, and a gate insulating pattern GOX, which are components of a vertical channel transistor.

The active patterns AP may include a first active pattern AP1 and a second active pattern AP2. In some embodiments, the first and second active patterns AP1 and AP2 may include a single crystal semiconductor material. For example, the first and second active patterns AP1 and AP2 may include single crystal silicon. For example, the active patterns AP may be formed by patterning the silicon material 103 of the SOI structure.

Each of the first and second active patterns AP1 and AP2 may have a length in a first direction D1, a width in a second direction D2, and a height in a third direction D3 perpendicular to the substrate 100. Each of the first and second active patterns AP1 and AP2 may have a substantially uniform width.

Terms such as “perpendicular,” “same,” “equal,” “uniform” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Each of the first and second active patterns AP1 and AP2 may have a first side surface (not shown) and a second side surface (not shown) facing away from each other in the second direction D2. The first side surface of the first active pattern AP1 may be adjacent to a first word line WL1 in the second direction D2, and the second side surface of the second active pattern AP2 may be adjacent to a second word line WL2 in the second direction D2.

Channel regions included in the first and second active patterns AP1 and AP2 may be controlled by the first and second word lines WL1 and WL2 and/or back gate electrodes BG during an operation of a semiconductor device 20, 20a, 20b, 30, or 40 which is described later. Because the first and second active patterns AP1 and AP2 include a single crystal semiconductor material, leakage current characteristics may be improved during the operation of the semiconductor device 20, 20a, 20b, 30, or 40.

The back gate electrodes BG may be arranged to be apart from each other by a certain interval in the second direction D2. The back gate electrodes BG may extend in the first direction D1.

Though not shown in the drawings, each of the back gate electrodes BG may be located between the first and second active patterns AP1 and AP2 adjacent to each other in the second direction D2. For example, the first active pattern AP1 may be located on one side of each of the back gate electrodes BG and the second active pattern AP2 may be located on the other side thereof.

The back gate electrodes BG may include, for example, doped polysilicon, a conductive metal nitride (e.g., titanium nitride, tantalum nitride, etc.), a metal (e.g., tungsten, titanium, tantalum, etc.), a conductive metal silicide, a conductive metal oxide, or combinations thereof.

Throughout the specification, when a component is described as “including” a particular clement or group of elements, it is to be understood that the component is formed of only the clement or the group of elements, or the clement or group of elements may be combined with additional elements to form the component, unless the context indicates otherwise. The term “consisting of,” on the other hand, indicates that a component is formed only of the element(s) listed.

To the back gate electrodes BG a negative voltage may be applied during the operation of the semiconductor device 20, 20a, 20b, 30, or 40, thereby increasing a threshold voltage of the vertical channel transistor. The increased threshold voltage may prevent leakage current characteristics from deteriorating, even as the minimal spacing/pitch of the vertical channel transistor's layout is reduced.

The vertical channel transistor may be a transistor in which the current flows vertically relative to the plane of the substrate. For example, the current may flow between source and drain in a direction, in which the semiconductor device is built (e.g., a plurality of layers are stacked in the direction). The current of the vertical channel transistor may flow in a direction along which memory patterns (described later) are stacked.

The first and second word lines WL1 and WL2 may extend in the first direction D1 and be arranged alternately in the second direction D2.

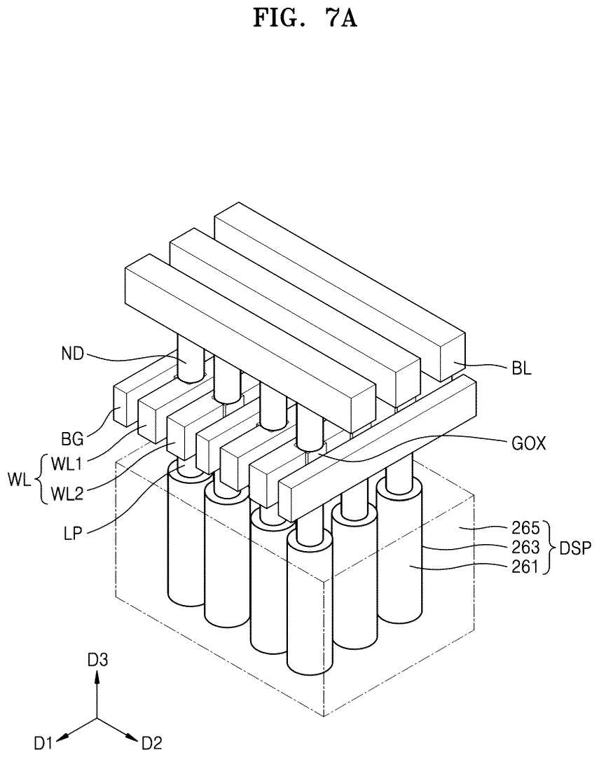

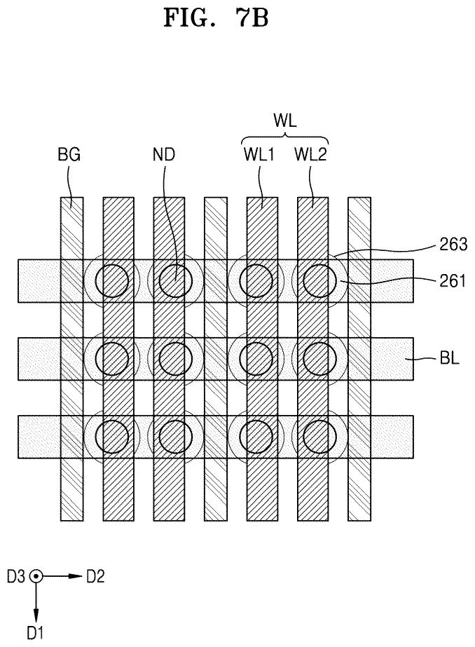

The first word line WL1 may be located on one side of the first active pattern AP1, and the second word line WL2 may be located on the one side of the second active pattern AP2 such that the first and word lines and the first and second active patterns are disposed symmetrically with respect to a line extending parallel to the first direction D1 in a plan view. The first and second word lines WL1 and WL2 may be vertically apart from the bit lines (BL, FIG. 7A).

The first and second word lines WL1 and WL2 may have a width in the second direction D2. The first word line WL1 may be arranged such that a portion thereof is disposed between the first active patterns AP1 which are disposed adjacent to each other in the first direction D1. The second word lines WL2 may be arranged such that a portion thereof is disposed between the second active patterns AP2 which are disposed adjacent to each other in the first direction D1.

The first and second word lines WL1 and WL2 may include, for example, doped polysilicon, a metal, a conductive metal nitride, a conductive metal silicide, a conductive metal oxide, or combinations thereof.

The first and second word lines WL1 and WL2 adjacent to each other may have sidewalls facing each other.

The gate insulating patterns GOX may be located between the first word line WL1 and the first active pattern AP1, and between the second word line WL2 and the second active pattern AP2. The gate insulating patterns GOX may extend in the first direction D1 parallel to the first and second word lines WL1 and WL2. The gate dielectric pattern GOX may have a substantially uniform thickness.

The gate insulating pattern GOX may include a silicon oxide film, a silicon oxynitride film, a high-k film having a higher dielectric constant than the silicon oxide film, or combinations thereof. The high-k dielectric film may include a metal oxide or a metal oxynitride. For example, the high-k dielectric film usable as the gate insulating patterns GOX may include, though the invention is not limited thereto, HfO₂, HfSiO, HfSiON, HfTaO, HfTiO, HfZrO, ZrO2, Al₂O₃, or combinations thereof.

In some embodiments, each of the first and second active patterns AP1 and AP2 may have an upper end and a lower end. For example, the upper and lower ends each may be connected to a corresponding one of source/drain patterns (or regions) which are not shown in the drawings.

In some embodiments, each of the first and second active patterns AP1 and AP2 may have an upper end and a lower end. For example, though not shown in the drawings, the upper and lower ends each may be one of source/drain patterns (or regions).

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

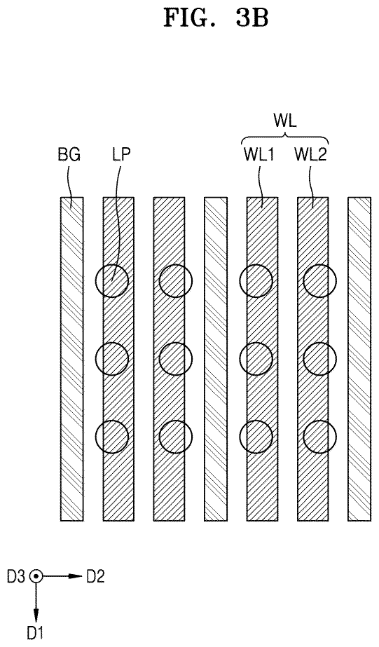

Next, referring to FIGS. 3A and 3B, a landing pad LP may be formed. The landing pad LP may be located to contact or electrically connected to at least a portion of the first and second active patterns AP1 and AP2. In some embodiments, the landing pad LP may be located to contact at least a portion of the source/drain patterns. Although only the landing pad LP is illustrated in FIGS. 3A and 3B, in some other embodiments, an additional contact pattern may be formed first on the first and second active patterns AP1 and AP2, and then the landing pad LP may be located on the additional contact pattern.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diode

Each of the landing pads LP may have various shapes, such as circular, oval, rectangular, square, rhombus, or hexagonal shape, in a plan view. The landing pads LP may include, though the invention is not limited thereto, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or combinations thereof.

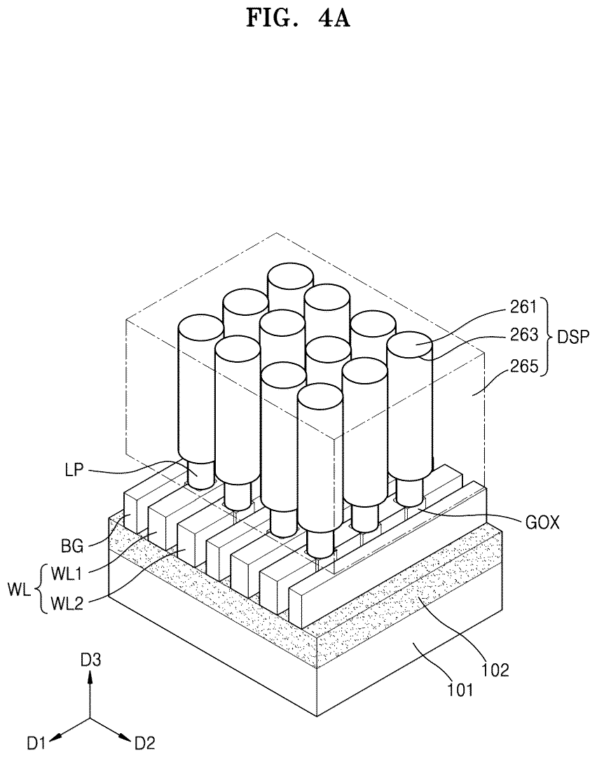

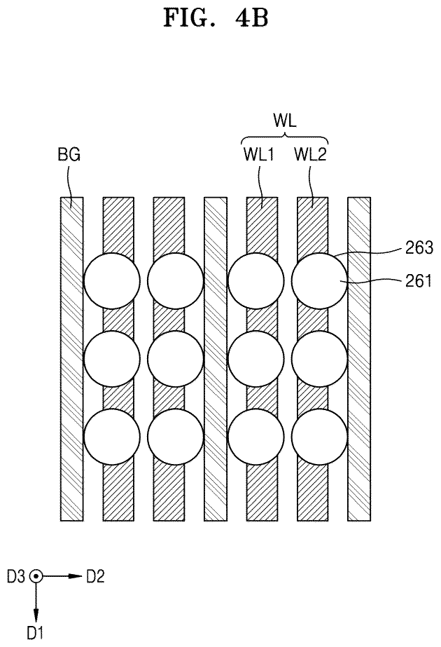

Referring to FIGS. 4A and 4B, data storage patterns DSP may be located on the landing pads LP. The data storage patterns DSP may be electrically connected to the first and second active patterns AP1 and AP2, respectively. The data storage patterns DSP may be arranged in a matrix form in the first direction D1 and the second direction D2. The data storage patterns DSP may fully or partially overlap the landing pads LP. The data storage patterns DSP may contact all or part of upper surfaces of the landing pads LP.

In some embodiments, the data storage patterns DSP may be capacitors and may include a capacitor dielectric film (not shown) on the surface 263 of the data storage patterns DSP located between storage electrodes 261 and a plate electrode 265. In this case, the storage electrode 261 may be in direct contact with the landing pad LP and may have various shapes, such as circular, oval, rectangular, square, rhombus, or hexagonal shape, in a plan view. Each of the storage electrodes 261 may be electrically connected to a corresponding one of the source/drain patterns

Alternatively, the data storage patterns DSP may be variable resistance patterns that may be switched between two resistance states by electrical pulses applied to memory elements (variable resistance patterns). For example, the data storage patterns DSP may include, though the invention is not limited thereto, a phase-change material having crystal states interchanging depending on the amount of current, a perovskite compound, a transition metal oxide, a magnetic material, a ferromagnetic material, an antiferromagnetic material, etc. or combinations thereof.

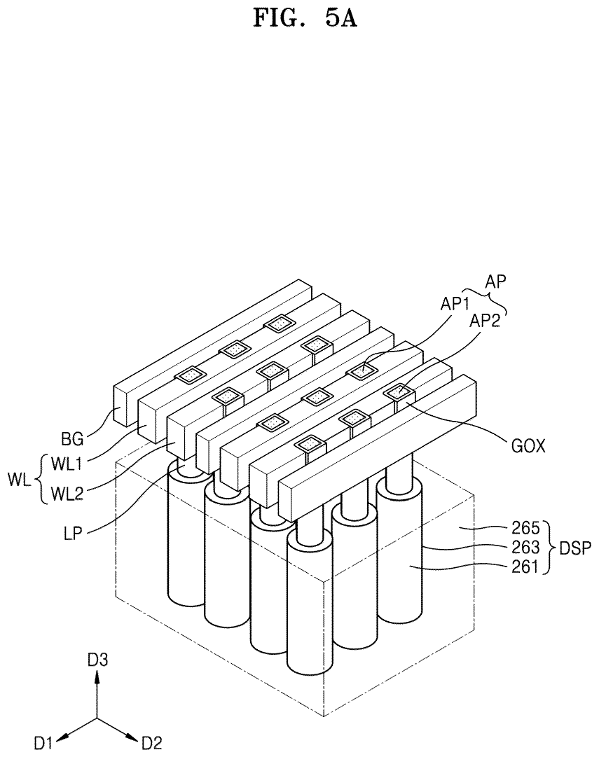

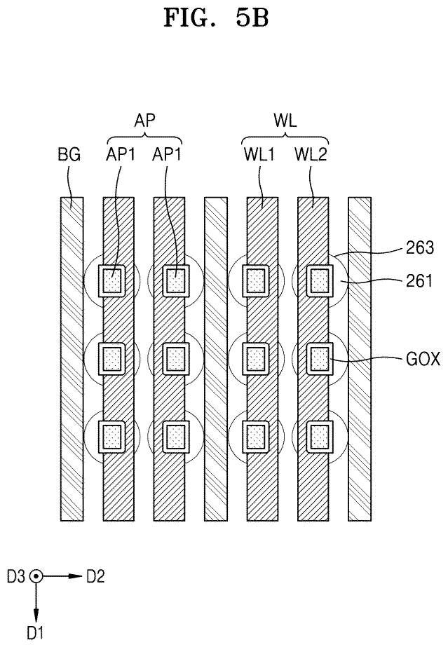

Referring to FIGS. 5A and 5B, the resultant structure of FIGS. 4A and 4B may be turned over so that the data storage patterns DSP are at the bottom and the word lines WL, the back gate electrodes BG, and the first and second active patterns AP1 and AP2 are located at the top. For example, upper surfaces of the word lines WL, back gate electrodes BG, and first and second active patterns AP1 and AP2 may be exposed through the overturning process and a process of removing the insulating material 102 and the silicon material 101.

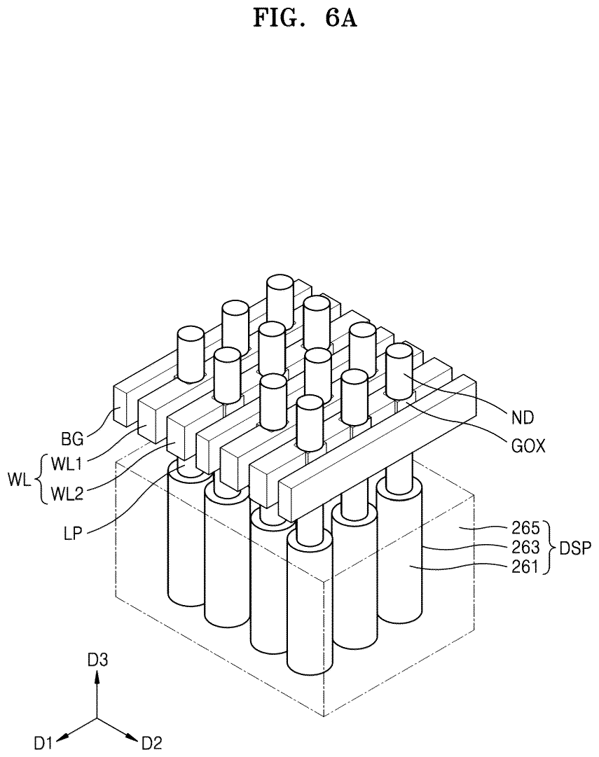

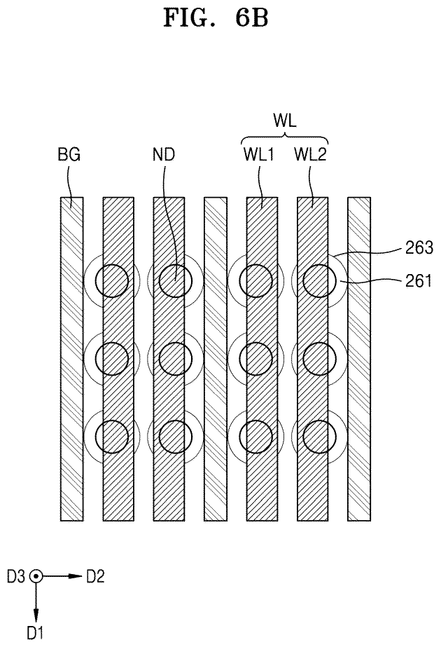

Next, referring to FIGS. 6A and 6B, contact nodes ND may be formed at positions at which the contact nodes ND overlap at least partially the upper surfaces of the first and second active patterns AP1 and AP2, respectively.

Each of the act nodes ND (which may be bit line contacts) may be electrically connected to a corresponding one of the first and second active patterns AP1 and AP2. In some embodiments, each of the act nodes ND may contact a corresponding one of the source/drain patterns (not shown).

In FIGS. 6A and 6B, the contact nodes LP are illustrated as being circular in the plan view, but the inventive concept is not limited thereto, and each of the contact nodes LP may have various shapes, such as circular, oval, rectangular, square, rhombus, or hexagonal, in the plan view.

Next, referring to FIGS. 7A and 7B, the bit lines BL may be formed that are spaced apart in the first direction D1 and extend in the second direction D2 intersecting the first direction D1. The bit lines BL may be formed so that lower surfaces thereof are in contact with upper surfaces of the contact nodes ND. Each of the bit lines BL may be electrically connected to a corresponding one of the source/drain patterns.

In some embodiments, each of the bit lines BL may include a polysilicon pattern, a metal pattern, and a hard mask pattern, which are sequentially stacked. The metal pattern may include a conductive metal nitride (e.g., titanium nitride, tantalum nitride, etc.) or a metal (e.g., tungsten, titanium, tantalum, etc.). Alternatively, the metal pattern may include a metal silicide, such as titanium silicide, cobalt silicide, or nickel silicide. The hard mask pattern may include an insulating material, such as silicon nitride or silicon oxynitride.

Referring to FIGS. 8A, 8B and 8C, a spacer SP and a bit line shield layer BLS may be formed so as to fill the spaces (gaps) between the bit lines BL which are spaced apart in the first direction D1. A bit line plate BLP that covers the top of the bit line shield layer BLS may be formed. Hereinafter, a resultant structure of FIGS. 8A and 8B may be referred to as a memory pattern 10.

The spacer SP, bit line shield layer BLS, and bit line plate BLP may be understood in more detail with reference to FIG. 8C. FIG. 8C is a cross-sectional view schematically illustrating a portion of a section taken along line A1-A1′ in FIG. 8A.

Referring to FIG. 8C, the spacer SP that covers both the side and upper surfaces of the contact nodes ND and bit lines BL located on the word line WL may be first formed.

The spacer SP may include an insulating material. The spacer SP may be formed of, for example, silicon oxide, silicon oxynitride, silicon nitride, silicon carbide, or combinations thereof.

Next, the bit line shield layer BLS may be formed on the spacer SP. The bit line shield layer BLS may be formed to cover the entire upper surface of the spacer SP. In some embodiments, the bit line shield layer BLS may include TiN.

Finally, the bit line plate BLP may be formed on the bit line shield layer BLS. The bit line plate BLP may be formed thicker in the third direction D3 than the bit line shield layer BLS. For example, the bit line plate BLP may be formed to be thicker in the third direction D3 as compared to the bit line shield layer BLS. For example, a thickness of the bit line plate BLP in the third direction D3 may be 100 Å or more.

For example, the bit line plate BLP may include at least one selected from TiN, W, polysilicon, polysilicon germanium, and combinations thereof.

In embodiments, the bit line plate BLP may include W. In some other embodiments, the bit line plate BLP may include TiN. In this case, the bit line plate BLP may include TiN having a higher Ti content than the TiN included in the bit line shield layer BLS.

In FIG. 8C, although the bit line shield layer BLS and the bit line plate BLP are sequentially stacked on the spacer SP, the inventive concept is not limited thereto and the bit line shield layer BLS and the bit line plate BLP may be formed integrally.

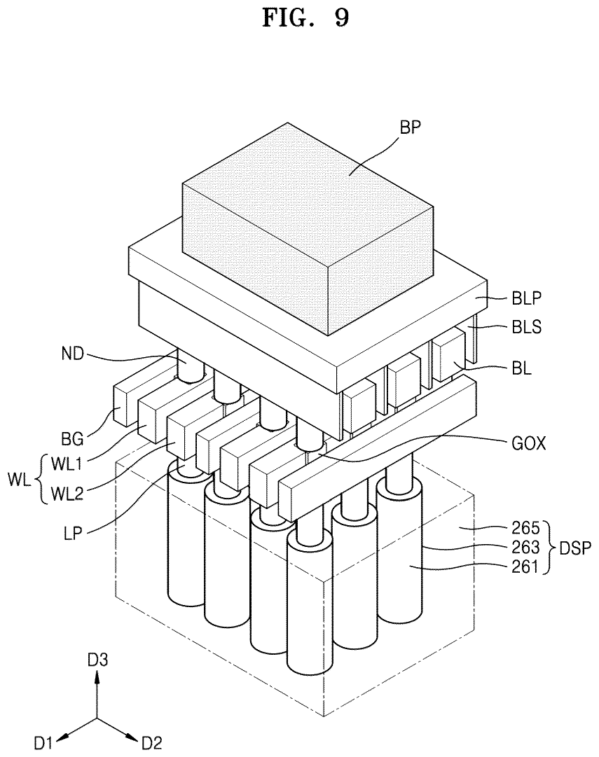

Next, referring to FIG. 9, a bonding pattern BP may be formed on the memory pattern 10, which is the resultant structure described above with reference to FIGS. 8A to 8C. The bonding pattern BP may be formed on the bit line plate BLP. In FIG. 9, the bonding pattern BP is illustrated as being formed smaller than the bit line plate BLP, but this is only an example, and the shape and size of the bonding pattern BP are not limited to those illustrated in FIG. 9 and the drawings below. The bonding pattern BP may be directly connected to the bit line plate BLP.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The bonding pattern BP may include, for example, copper. The bonding pattern BP may be formed by a damascene process. Though not shown in the drawings, the bonding pattern BP may be wiring layers and/or patterns. For example, the wiring patterns may include at least one selected from a copper (Cu) pad, a contact, a via, a metal interconnection structure (metal interconnection pattern), and combinations thereof.

In some embodiments, at least one metal interconnection structure (e.g., metal patterns) may be further provided between the bonding pattern BP and the bit line plate BLP.

Referring to FIG. 10A, after forming two memory patterns (10, see FIG. 8A), the bonding pattern BP (see FIG. 9) is formed on each of the memory patterns (10, see FIG. 8A), and bonding patterns BPa and BPb of the respective resultant structures may be brought into contact with each other to form the semiconductor device 20 through a Cu-to-Cu bonding and annealing process.

For example, the semiconductor device 20 may be a two-stack device including two of the memory patterns 10. Throughout the specification, in the drawings and the related description, like features and elements may be identified by the same or similar reference numerals and/or letters, and duplicate descriptions may be omitted for the purpose of simplicity and clarity.

The semiconductor device 20 may have a mirror-symmetrical structure based on the bonding patterns BPa and BPb. For example, the semiconductor device 20 may include a pair of the memory patterns 10. The bonding patterns BPa and BPb may be formed on the memory patterns 10. As a result, the same structures may be symmetrically disposed with respect to a plane (which is an interface between the bonding patterns BPa and BPb), thereby forming stacked patterns. Each of the stacked patterns may be a segment of a memory cell array.

In addition, because the semiconductor device 20 is a two-stack device, the semiconductor device 20 may include twice as many word lines WLa and WLb, bit lines BLa and BLb, and data storage patterns DSPa and DSPb as the memory pattern 10. For example, the semiconductor device 20 may include two segments of a memory cell array. Each of the memory cell segments may include a corresponding one of word lines (WLa or WLb), a corresponding one of bit lines (BLa or BLb), and a corresponding one of data storage patterns (DSPa or DSPb).

The unit cell may store a bit of data. Each unit cell may consist of a combination of electronic components that are arranged in a way that allows for the storage, retrieval, and manipulation of a single bit of data within a memory cell array. Unit cells may be designed as the most basic functional building block that stores a single bit of data. In the memory cell array, unit cells may be arranged in a grid-like fashion, and each cell may be addressed by a combination of row and column lines.

In some embodiments, each of the vertical channel transistors and the corresponding one of data storage patterns (DSPa or DSPb) may be components of a sub-cell (part of a unit cell) of the memory array. Each of the memory cell segments includes an array of the sub-cells. Each of the sub-cells in one of the memory cell segments and a corresponding one of the sub-cells in the other of the memory cell segments may constitute a unit cell of the memory cell array of the semiconductor device 20.

In some embodiments, each of the word lines WLa may be electrically connected to a corresponding one of the word lines WLb by wiring layers and/or patterns disposed between the two memory cell segments. Further, each of the bit lines BLa may be electrically connected to a corresponding one of the bit lines BLb by wiring layers and/or patterns disposed between the two memory cell segments.

In some embodiments, in each of the unit cells, a sub-cell in one of the memory cell segments and a corresponding sub-cell in the other of the memory cell segments may overlap with each other, in a plan view.

For example, the bit line plates BLPa and BLPb and the bonding patterns BPa and BPb may be replaced by wiring layers and/or patterns such that each of the plurality of unit memory cells includes two sub-cells. The two sub-cells may be disposed at different height levels from each other. The two sub-cells may be electrically connected to each other by the wiring layers and/or patterns, there forming a plurality of unit memory cells.

FIG. 10B is a cross-sectional view illustrating the relatively decreased area occupied by a unit memory cell according to the embodiment described with reference to FIG. 10A. FIG. 10B includes two cross-sectional plan views (or layout diagrams showing storage electrodes). The right side shows the reference view, which illustrates an array of memory cells of the semiconductor device 10A according to the embodiments. The left side shows the reference view, which illustrates an array of cells of a one-stack device (a memory cell array having only one of the memory patterns 10). It is assumed that the semiconductor device of the left side includes a vertical channel transistor having the same minimal spacing/pitch of its layout as the vertical channel transistor of the semiconductor device 20. It is also assumed that the semiconductor device of the left side includes a capacitor having the same configuration as the capacitor of the semiconductor device 20 with respect to the structural and material configuration.

In the case of the layout diagram on the left, the unit area of the unit cell including one storage electrode may correspond to a², while, with reference to the layout diagram on the right, the unit area of the unit cell including one storage electrode may correspond to 2a². That is, the semiconductor device 20 in which the diameter of the storage electrode is increased by about 1.414 times may improve reliability related to interconnection separation, and a resistance reduction effect between the bit line and the capacitor may also be expected.

For example, assuming the capacitance of a capacitor (data storage patterns DSP) of a unit cell in the semiconductor device 20 is the same as that of a capacitor of a unit cell of the reference cell array, the area occupied by a unit memory cell of the embodiment of the present invention may be significantly decreased.

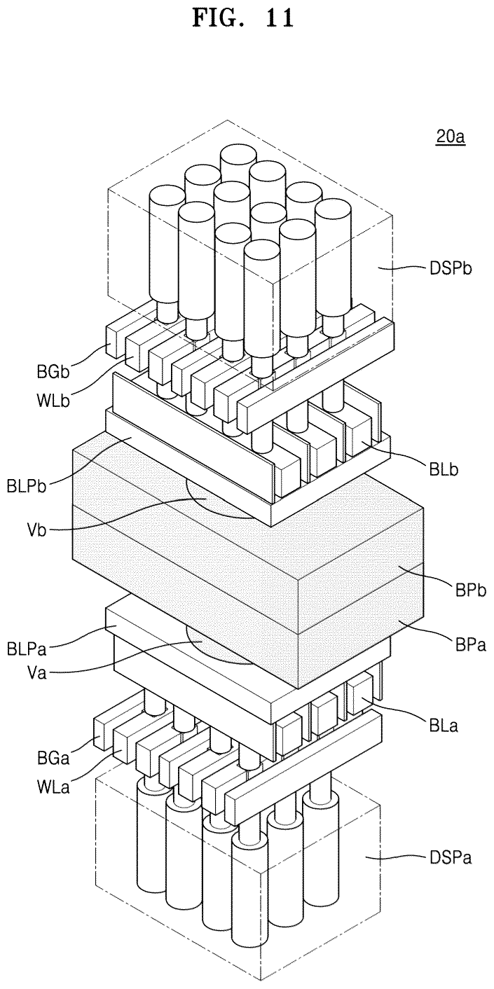

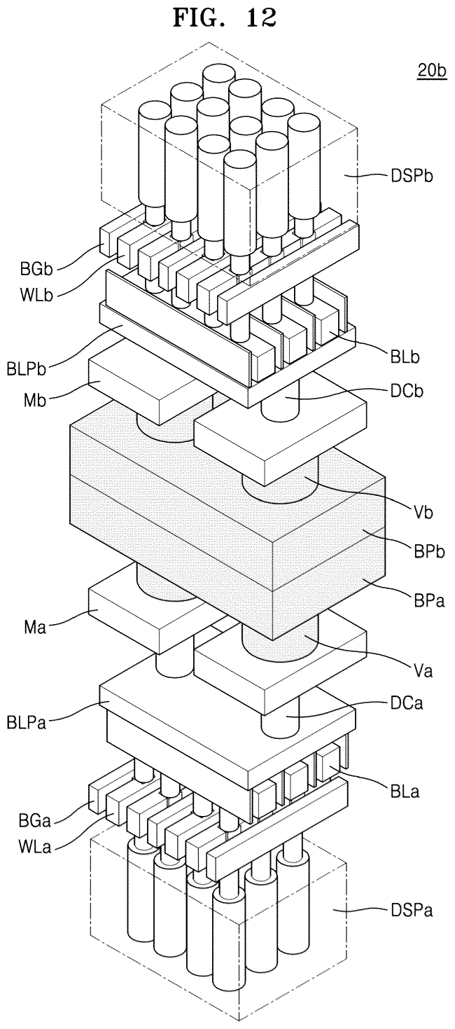

FIGS. 11 and 12 illustrate other possible embodiments of a two-stack device.

Referring to FIG. 11, the semiconductor device 20a may have the same configuration as the semiconductor device 20 of FIG. 10, but may further include contact vias Va and Vb, each of which is disposed between a corresponding one of the bonding patterns BPa and BPb and a corresponding one of the bit line plates BLPa and BLPb. In FIG. 11, the contact vias Va and Vb are illustrated as having a cylindrical shape, and the invention is not limited to the shape and size illustrated in FIG. 11. In FIG. 11, between each of the bonding patterns BPa and BPb and a corresponding one of the bit line plates BLPa and BLPb, though it is illustrated that one of the contact vias Va and Vb is formed, the invention is not limited to the number of the contact vias illustrated in FIG. 11. For example, between the bonding pattern BPa and the bit line plate BLPa, a plurality of contact vias may be formed.

Referring to FIG. 12, the semiconductor device 20b may have the same configuration as the semiconductor device 20 of FIG. 10, but may further include contact vias Va and Vb, interconnection patterns Ma and Mb, and contact patterns DCa and DCb. For example, the semiconductor device 20b may have the same configuration as the semiconductor device 20a of FIG. 11, but may further include interconnection patterns Ma and Mb and contact patterns DCa and DCb. Between each of the bonding patterns BPa and BPb and a corresponding one of the bit line plates BLPa and BLPb, a plurality of contact vias may be formed.

In FIG. 12, the interconnection patterns Ma and Mb are illustrated as having a rectangular shape, but the invention is not limited to the shape and size illustrated in FIG. 12. Similarly, the contact patterns DCa and DCb are illustrated as being cylindrical, but the invention is not limited thereto. In FIG. 12, between each of the contact vias Va and Vb and a corresponding one of the bit line plates BLPa and BLPb, though it is illustrated that one of the contact patterns DCa and DCb is formed, the invention is not limited to the number of the contact vias illustrated in FIG. 12, and a plurality of contact patterns may be formed. Similarly, in FIG. 12, between each of the contact vias Va and Vb and a corresponding one of the bit line plates BLPa and BLPb, though it is illustrated that one of the interconnection patterns Ma and Mb is formed, the invention is not limited to the number of the contact vias illustrated in FIG. 12, and a plurality of interconnection patterns may be formed.

Referring to FIG. 13A, in resultant structures obtained by forming three memory patterns (10, refer to FIG. 8A) and forming the bonding pattern BP (refer to FIG. 9) on two of the memory patterns (10, refer to FIG. 8A). Bonding patterns BPc and BPd of the resultant structures may be brought into contact with each other, which is subjected to a Cu-to-Cu bonding and annealing process to form the two-stack semiconductor device (20, refer to FIG. 11A). The bonding pattern BPb may be formed on the data storage pattern DSPb disposed below the two-stack semiconductor device 20. The bonding pattern BPa may be formed on the memory pattern 10. Then, the bonding patterns BPa and BPb may be attached to each other to form the semiconductor device 30. The semiconductor device 30 may be a three-stack device including three memory patterns 10.

For example, the semiconductor device 30 may include the same configuration (two-stack device) as the semiconductor device 20 of FIG. 10A, and further include the same configuration (lower stack structure) as the memory pattern 10 shown in FIG. 8A. Like features and elements may be identified by the same or similar reference numerals and/or letters, and duplicate descriptions may be omitted for the purpose of simplicity and clarity. Between the two-stack device and the lower stack structure, the bonding patterns BPa and BPb may be disposed.

The bonding between the bonding patterns (between the bonding pattern BPd and the bonding pattern BPc and between the bonding pattern BPb and the bonding pattern BPa) may be performed by a Cu-to-Cu bonding and annealing process, and the bonding between the bonding patterns and the data storage patterns (between the bonding pattern BPb and the data storage pattern DSPb and between the bonding pattern BPa and the data storage pattern DSPa) may be performed by a damascene process. As described in other embodiments of the two-stack device (20a, see FIGS. 11, and 20b, see FIG. 12), the bonding structures are not limited to the example of FIG. 13A and other interconnections, vias, or contacts may be located therebetween.

The semiconductor device 30 is a three-stack device and thus may include three times as many word lines WLa, WLb, and WLc, bit lines BLa, BLb, and BLc and data storage patterns DSPa, DSPb, and DSPc as the memory pattern 10. For example, the semiconductor device 30 may include three of the same configuration as the memory pattern 10 shown in FIG. 8A.

For example, the bit line plates BLPa, BLPb and BLPc and the bonding patterns BPa, BPb, BPc and BPd may be replaced by wiring layers and/or patterns such that each of the plurality of unit memory cells includes three sub-cells. The three sub-cells may be disposed at different height levels from each other. The three sub-cells may be electrically connected to each other by the wiring layers and/or patterns, thereby forming a plurality of unit memory cells.

Referring to FIG. 13B, assuming that a semiconductor device including a vertical channel in the same cross-sectional area is formed, in the case of the layout diagram on the left, the extent of the unit area including one storage electrode may correspond to a², while, with reference to the layout diagram on the right, the extent of the unit area including one storage electrode may correspond to 3a². That is, the semiconductor device 30 in which the diameter of the storage electrode is increased by about 1.732 times may improve reliability related to interconnection separation, and a resistance reduction effect between the bit line and the capacitor may also be expected.

Referring to FIG. 14A, in resultant structures obtained by forming four memory patterns (10, see FIG. 8A) and bonding two of the memory patterns (10, see FIG. 8A). The bonding pattern BPd may be formed below the data storage pattern DSPc of one resultant structure, and the bonding pattern BPc may be formed above the data storage pattern DSPb of the other resultant structure. The bonding patterns BPc and BPd may be brought into contact with each other and are subjected to a Cu-to-Cu bonding and annealing process to form a four-stack semiconductor device. The semiconductor device 40 may be a four-stack device including four memory patterns 10.

For example, the semiconductor device 40 may include two of the same configuration (two-stack device) as the semiconductor device 20 of FIG. 10A. Like features and elements may be identified by the same or similar reference numerals and/or letters, and duplicate descriptions may be omitted for the purpose of simplicity and clarity. Between the two of the two-stack devices, the patterns bonding BPc and BPd may be disposed.

The bonding between the bonding patterns (between the bonding pattern BPf and the bonding pattern BPe, between the bonding pattern BPd and the bonding pattern BPc, and between the bonding pattern BPb and the bonding pattern BPa) may be performed by a Cu-to-Cu bonding and annealing process, and the bonding between the bonding patterns and the data storage patterns (between the bonding pattern BPd and the data storage pattern DSPc and between the bonding pattern BPc and the data storage pattern DSPb) may be performed by a damascene process. As described in other embodiments of the two-stack device (20a, see FIGS. 11, and 20b, see FIG. 12), the bonding structures are not limited to the example of FIG. 14A and other interconnections, vias, or contacts may be located therebetween.

The semiconductor device 40 is a 4-stack device and thus may include four times as many word lines WLa, WLb, WLc and WLd, bit lines BLa, BLb, BLc, and BLd and data storage patterns DSPa, DSPb, DSPc, and DSPd as the memory pattern 10. For example, the semiconductor device 40 may include four of the same configuration as the memory pattern 10 shown in FIG. 8A.

For example, the bit line plates BLPa, BLPb, BLPc and BLPd and the bonding patterns BPa, BPb, BPc, BPd, BPe and BPf may be replaced by wiring layers and/or patterns, such that each of the plurality of unit memory cells includes four sub-cells. The four sub-cells may be disposed at different height levels from each other.

Referring to FIG. 14B, assuming that a semiconductor device including a vertical channel in the same cross-sectional area is formed, in the case of the layout diagram on the left, the extent of the unit area including one storage electrode corresponds to a², while, with reference to the layout diagram on the right, the extent of the unit area including one storage electrode may correspond to 4a². That is, the semiconductor device 40 with a doubled storage electrode diameter may have improved reliability related to interconnection separation, and a resistance reduction effect between the bit line and the capacitor may also be expected.

Although up to 4 stack semiconductor devices are illustrated in this specification, these are only some of the embodiments, and according to the method of forming the memory pattern (10, see FIG. 8A) described above with reference to FIGS. 1 to 9 and the method of forming bonding patterns, five or more stacks may be formed.

While the inventive concept has been particularly shown and described with reference to embodiments thereof, it will be understood that various changes in form and details may be made therein without departing from the spirit and scope of the following claims.

What is claimed is:

1. A semiconductor device comprising:
a first memory pattern, a first bonding pattern on the first memory pattern, a second bonding pattern on the first memory pattern, and a second memory pattern on the second bonding pattern,
wherein the first memory pattern includes:
a first active pattern including first and second side surface facing away from each other;
a second active pattern including third and fourth side surface facing away from each other;
a first word line extending in a first direction from the first side surface of the first active pattern;
a second word line extending in the first direction from the fourth side surface of the second active pattern;
a back gate electrode extending in the first direction and spaced apart from the first and second word lines in a second direction perpendicular to the first direction;
data storage patterns each including a capacitor;
landing pads each having:
a first end portion contacting a corresponding one of lower surfaces of the first and second active patterns, and
a second end portion contacting a corresponding one of the data storage patterns;
contact nodes, each of the contact nodes disposed on a corresponding one of upper surfaces of the first and second active patterns;
bit lines, each of the bit lines contacting a corresponding one of the contact nodes and extending in the second direction;
a bit line shield layer covering upper and side surfaces of the bit line; and
a first bit line plate covering an upper surface of the bit line shield layer, wherein the second memory pattern is symmetric to the first memory pattern.

2. The semiconductor device of claim 1, wherein each of the first and second bonding patterns includes a copper (Cu) pad.

3. The semiconductor device of claim 1, wherein:
the second memory pattern includes a second bit line plate; and
the first and second bonding patterns are connected to the first and second bit line plates of the first and second memory patterns, respectively.

4. The semiconductor device of claim 1, wherein the bit line shield layer includes TiN, and the each of the first and second bit line plates includes at least one selected from TiN, W, polysilicon, polysilicon germanium, and combinations thereof.

5. The semiconductor device of claim 1, wherein the first bit line plate has a thickness, in a third direction intersecting the first direction and the second direction, is greater than a thickness of the bit line shield layer in the third direction.

6. The semiconductor device of claim 5, wherein the thickness of the bit line plate in the third direction is 100 Å or greater.

7. The semiconductor device of claim 1, wherein the first memory pattern further includes a first contact via between the first bonding pattern and the first bit line plate of the first memory pattern and a second contact via between the second bonding pattern and the second bit line plate of the second memory pattern.

8. The semiconductor device of claim 1, further comprising a first metal interconnection pattern provided between the first bonding pattern and the first bit line plate of the first memory pattern and a second metal interconnection pattern between the second bonding pattern and the second bit line plate of the second memory pattern.

9. The semiconductor device of claim 1, wherein the first memory pattern further includes a spacer between the bit lines and the bit line shield layer.

10. A semiconductor device comprising:
a first memory pattern including:
a first active pattern including first and second side surface facing away from each other,
a second active pattern including third and fourth side surface facing away from each other,
a first word line extending in a first direction from the first side surface of the first active pattern,
a second word line extending in the first direction from the fourth side surface of the second active pattern,
a back gate electrode extending in the first direction and being spaced apart from the first and second word lines in a second direction perpendicular to the first direction,
first data storage patterns each including a capacitor,
landing pads each having:
a first end portion contacting a corresponding one of lower surfaces of the first and second active patterns, and
a second end portion contacting a corresponding one of the first data storage patterns,
contact nodes, each of the contact nodes located on a corresponding one of upper surfaces of the first and second active patterns,
bit lines, each of the bit lines contacting a corresponding one of the contact nodes and extending in the second direction,
a bit line shield layer covering upper and side surfaces of the bit line, and p2 a first bit line plate covering an upper surface of the bit line shield layer;
a second memory pattern is symmetric to the first memory pattern and disposed at a vertical level higher than the first memory pattern;
a first bonding pattern and a second bonding pattern connecting the first memory pattern to the second memory pattern;
a third memory pattern is symmetric to the first memory pattern and disposed at a vertical level lower than the first memory pattern; and
a third bonding pattern and a fourth bonding pattern connecting the third memory pattern to the first memory pattern,
wherein:
the second memory pattern includes a second data storage pattern and a second bit line plate spaced apart from each other,
the third memory pattern includes a third data storage pattern and a third bit line plate spaced apart from each other,
the first bonding pattern and the third bonding pattern are connected to the first bit line plate and the first data storage pattern of the first memory pattern, respectively,
a lower surface and an upper surface of the second bonding pattern are connected to the first bonding pattern and the second bit line plate of the second memory pattern, respectively, and
a lower surface and an upper surface of the fourth bonding pattern are connected to the third data storage pattern and the third bonding pattern of the third memory pattern, respectively.

11. The semiconductor device of claim 10, wherein the first, second, third, and fourth bonding patterns include at least one selected from a copper pad, a contact, a via, a metal interconnection pattern, and combinations thereof.

12. The semiconductor device of claim 10, wherein the bit line shield layer includes TiN, and the first bit line plate includes at least one selected from TiN, W, polysilicon, polysilicon germanium, and combinations thereof.

13. The semiconductor device of claim 10, wherein a thickness of the first bit line plate in a third direction intersecting the first direction and the second direction is greater than a thickness of the bit line shield layer in the third direction.

14. The semiconductor device of claim 13, wherein the thickness of the first bit line plate in the third direction is 100 Å or greater.

15. The semiconductor device of claim 10, wherein a spacer is further provided between the bit lines and the bit line shield layer.

16. A semiconductor device comprising:
a first memory pattern including:
a first active pattern including first and second side surface facing away from each other,
a second active pattern including third and fourth side surface facing away from each other,
a first word line extending in a first direction from the first side surface of the first active pattern,
a second word line extending in the first direction from the fourth side surface of the second active pattern,
a back gate electrode extending in the first direction and being spaced apart from the first and second word lines in a second direction perpendicular to the first direction,
data storage patterns each including a capacitor,
landing pads each having:
a first end portion contacting a corresponding one of lower surfaces of the first and second active patterns, and
a second end portion contacting a corresponding one of the data storage patterns,
contact nodes, each of the contact nodes located on a corresponding one of upper surfaces of the first and second active patterns,
bit lines, each of the bit lines contacting a corresponding one of the contact nodes and extending in the second direction,
a spacer and a bit line shield layer sequentially surrounding an upper surface and a side surface of the bit line, and
a bit line plate covering an upper surface of the bit line shield layer;
at least one second memory pattern disposed at a different vertical level from the first memory pattern and being symmetric to the first memory pattern;
at least one third memory pattern disposed at a different vertical level from the first memory pattern and being symmetric to the first memory pattern; and
at least two bonding patterns connecting the first, second, and third memory patterns.

17. The semiconductor device of claim 16, wherein each of the two of the bonding patterns includes at least one selected from a copper pad, a contact, a via, a metal interconnection pattern, and combinations thereof.

18. The semiconductor device of claim 16, wherein:
the bit line shield layer includes TiN, and
the bit line plate includes at least one selected from TiN, W, polysilicon, polysilicon germanium, and combinations thereof.

19. The semiconductor device of claim 16, wherein a thickness of the bit line plate in a third direction intersecting the first direction and the second direction is greater than a thickness of the bit line shield layer in the third direction.

20. The semiconductor device of claim 19, wherein the thickness of the bit line plate in the third direction is 100 Å or greater.

21. A semiconductor device comprising:
a first plurality of sub-cells disposed at a first vertical height level in a first direction; and
a second plurality of sub-cells disposed at a second vertical height level in the first direction,
wherein:
each of the first plurality of sub-cells and a corresponding one of the second plurality of sub-cells are parts of a unit cell of a memory cell array,
each of the first plurality of sub-cells include a first transistor, and
each of the second plurality of sub-cells include a second transistor.

22. The semiconductor device of claim 21, wherein the first plurality of sub-cells and the second plurality of sub-cells are disposed symmetrically with respect to a plane located between the first plurality of sub-cells and the second plurality of sub-cells.

23. The semiconductor device of claim 22, wherein:
each of the first plurality of sub-cells further include a first data storage pattern, and
each of the second plurality of sub-cells further include a second data storage pattern.

24. The semiconductor device of claim 23, wherein the first and second transistors are vertical channel transistors.

25. The semiconductor device of claim 23, wherein the first and second data storage pattern are capacitors.
